(19) United States
(12) Patent Application Publication
(10) Pub. No.: US 2005/0109462 A1
(43) Pub. Date: May 26, 2005

(54) Apparatus for generating inductively-coupled plasma and antenna coil structure thereof for generating inductive electric fields

(75) Inventors: Young-Dong Lee, Gijang-gun (KR); Jai-Kwang Shin, Anyang-si (KR); Jae-Joon Oh, Seongnam-si (KR); Seong-Gu Kim, Pyeongtaek-si (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., GYEONGGI-DO (KR)

(21) Appl. No.: 10/909,467

(22) Filed: Aug. 2, 2004

(30) Foreign Application Priority Data
Nov. 21, 2003 (KR) 83059-2003

(51) Int. Cl. C23F 1/00; H01L 21/306; C23C 16/00

(52) U.S. Cl. 156/345.48

(57) ABSTRACT

Disclosed is an apparatus for generating inductively-coupled plasma (ICP). The ICP generation apparatus includes a source region where an ICP antenna coil is mounted, the ICP antenna coil generating inductive electric fields for generating plasma and having a serially-connected concentric circle-type structure, the total number of windings of the ICP antenna coil being greater than 2, the ICP antenna coil having a structure in which at least one circular winging closest to the center of the concentric circle is wound in a direction opposite to that of the other windings; a sealed chamber in which a predetermined process is performed on a sample placed on a chuck therein through a reaction between plasma ions and reactive radicals; and a radio frequency (RF) power supply for providing RF electric power of a predetermined frequency to the ICP antenna coil in the source region.

### PRIORITY

This application claims priority under 35 U.S.C. § 119 to an application entitled “Apparatus for Generating Inductively-Coupled Plasma and Antenna Coil Structure Thereof for Generating Inductive Electric Fields” filed in the Korean Intellectual Property Office on Nov. 21, 2003 and assigned Serial No. 2003-83059, the contents of which are incorporated herein by reference.

### BACKGROUND OF THE INVENTION

1. Field of the Invention

The present invention relates generally to an apparatus for generating plasma, and in particular, to an apparatus for generating inductively-coupled plasma and an antenna thereof for generating inductive electric fields.

2. Description of the Related Art

Plasma processing is used in the manufacturing processes of various devices such as semiconductor integrated circuits and Flat Panel Displays (FPD). Typically, plasma processing is used for various surface processes such as physical vapor deposition (PVD), plasma enhanced chemical vapor deposition (PECVD), dry etching, sputtering, in-situ chamber cleaning, plasma immersion ion implantation, etc.

Plasma generation technology for such plasma processing, inductively-coupled plasma (ICP), electron cyclotron resonance (ECR), and surface wave plasma (SWP) technologies have been developed.

Recently, development of plasma equipment for use in the production of semiconductors is focusing on widening a processing range for improving yield, and increasing the capability for high-integration processing. When it comes to cost reduction and increasing productivity, the sizes of the wafers for semiconductor devices or substrates for plane display devices a tend to increase to 300 mm or greater. In order to satisfy the growing processing range, securing a high-integration processing capability through the improvement in the uniformity in the process itself and generation of a high-density plasma must be achieved in the development of the plasma equipment.

In this regard, an ICP generation apparatus offers great advantages in that it can easily generate high-density plasma and is simple in its basic structure. Therefore, the ICP generation apparatus is attracting public attention as the next generation equipment for 300-mm wide wafers.

FIG. 1 is a perspective view of a general ICP generation apparatus. The structure of the general ICP generation apparatus will now be described with reference to FIG. 1. The general ICP generation apparatus as shown in FIG. 1is comprised of a source region 11 where an ICP antenna coil 12 for generating inductive electric fields is disposed to generate plasma, and a sealed chamber 10 where actual processing takes place through a complementary action of plasma ions and reactive radicals. The source region 11 is separated from the chamber 10 by an insulating plate 16.

The chamber 10 includes a gas inlet (not shown) for supplying reactive gas, a vacuum pump (not shown) for keeping the inside of the chamber 10 in a vacuum state, and a gas outlet (not shown) for discharging reactive gas after reaction is complete. In addition, the chamber 10 includes a chuck 14 on which a sample 20 such as a wafer or a glass substrate is placed for processing. In the source region 11 is installed an antenna coil 12 to which a radio frequency (RF) power supply 18 is connected the RF power supply 18 supplies an RF signal in the frequency range of 1 to 30 MHz (commonly, 13.56 MHz).

In such an ICP generation apparatus, the inside of the chamber 10 is initially evacuated by the vacuum pump, and then, reactive gas for generating plasma is injected into the chamber 10 through the gas inlet at an appropriate pressure. Thereafter, RF electric power is provided to the antenna coil 12 from the RF power supply 18. The antenna coil 12, provided with the RF electric power, creates time-varying magnetic fields perpendicular to the plane of the antenna coil 12. These magnetic fields form inductive electric fields within the chamber 10. The inductive electric fields heat electrons, which in turn generates plasma. The electrons collide with adjacent neutral radical particles, generating ions and radicals, and the generated ions and radicals are used for the plasma etching and the deposition processes. In addition, electric power is applied to the chuck 14 from a second RF power supply 19 in order to control the energy of ions incident on the sample 20. Between the RF power supply 18 and the antenna coil 12 (also between the RF power supply 19 and the chuck 14) is commonly provided an impedance matching circuit (not shown) for impedance matching.

In the ICP generation apparatus illustrated in FIG. 1, the antenna coil 12 has a single-lined helical structure. Such an antenna coil 12 having a single-lined helical structure is simple in structure and easy to manufacture and install, and due to its simplicity has been popularly adopted.

However, due to the inherent nature of single-lined helical antennas, antenna coil 12 exhibits properties like that of circular inductive coils connected in series, wherein the current flowing through each inductive coil is constant. In this case, the generated inductive electric fields are distributed non-uniformly. In FIG. 2, distributions of inductive electric waves generated by the antenna coil 12 are represented by a plurality of arrows. A direction of an arrow at a certain position represents the direction of a corresponding inductive electric field, and the size of the arrow represents the strength of the inductive electric field at-that position. As illustrated in FIG. 2, inductive electric fields are non-uniformly distributed such that the strength of the inductive electric fields is greatest at the central portion of the antenna coil 12 (strictly speaking, at a portion spaced apart from the center to some extent), and becomes less at the inner and outer portions.

FIG. 3 is a graph illustrating the density of plasma ions generated by the inductive electric fields having the non-uniform distribution illustrated in FIG. 2. In the graph of FIG. 3, characteristic curve A represents plasma ion density at a position relatively close to the antenna coil 12 within the chamber 10, i.e. a position close to the insulating plate 16, and characteristic curve B represents the plasma ion density at a position close to the sample 20.

As illustrated in the graph of FIG. 3, it can be noted from characteristic curve A that the plasma density close to the insulating plate 16 corresponds to the strength of the inductive electric fields illustrated in FIG. 2. It can be understood from characteristic curve A that the plasma density is low at the most central portion of chamber 10, highest at a portion around the center, and becomes gradually lower at the outer portions.

The characteristic curve B represents the plasma density on the sample 20, and as a whole, the plasma density on the sample 20 is less than the plasma density close to the insulating plate 16, represented by the characteristic curve A. That is, plasma formed near the insulating plate 16, having the density represented by the characteristic curve A, has high density at the most central portion on the sample 20 and lower density at the outer portions, as represented by the characteristic curve B, through a diffusion process and a reduction process at the outer portions. Because such plasma on the sample 20 directly reacts with the sample 20, a corresponding density characteristic must be considered during the design of a plasma generator.

As illustrated in FIG. 3, the non-uniform inductive electric field distribution create a situation where plasma density on the sample 20 within the chamber 10 is highest at the central portion of the chamber 10 (or the central portion of the sample 20) and becomes gradually lower at the outer portions. Because such non-uniform distribution of plasma density has a negative effect on process uniformity, the current ICP generation apparatus adopts various technologies in order to secure a uniform plasma density.

An example of technology for securing a uniform plasma density is disclosed in U.S. Pat. No. 5,346,578, entitled “Induction Plasma Source,” Jeffrey C. Benzing, et al., the contents of which are incorporated herein by reference. An ICP generation apparatus disclosed in U.S. Pat. No. 5,346,578 has a structure in which a chamber ceiling is manufactured in the form of a hemisphere and a helical antenna coil is wound around the hemispheric chamber ceiling. Due to a geometric characteristic of the hemispheric chamber ceiling, plasma density shows higher uniformity on the wafer located within the chamber.

An ICP generation apparatus disclosed in U.S. Pat. No. 6,170,428, entitled “Symmetric Tunable Inductively Coupled HDP-CVD Reactor,” Fred, C. Redeker, et al., the contents of which are incorporated herein by reference, has a structure in which a helical antenna wound along an axial direction in the form of a solenoid is added to the outside of a chamber to compensate for a plasma loss at outer portions within the chamber, so that the plasma has higher uniform density as a whole.

However, the ICP generation apparatuses disclosed in U.S. Pat. Nos. 5,346,578 and 6,170,428, are disadvantageous in that they are complex in structure and difficult to manufacture because of the dome-type chamber and the additional helical antenna are needed.

### SUMMARY OF THE INVENTION

It is, therefore, an object of the present invention to provide an inductively-coupled plasma (ICP) generation apparatus capable of securing high plasma generation efficiency and improving plasma uniformity, and an antenna structure thereof for generating inductive electric fields.

It is another object of the present invention to provide an ICP generation apparatus capable of improving plasma uniformity with a simple structure, and an antenna structure thereof for generating inductive electric fields.

In accordance with one aspect of the present invention, there is provided an apparatus for generating inductively-coupled plasma (ICP). The ICP generation apparatus comprises a source region where an ICP antenna coil is mounted, the ICP antenna coil for generating inductive electric fields to generate plasma and having a serially-connected concentric circle-type structure, the total number of windings of the ICP antenna coil being greater than 2, the ICP antenna coil having a structure in which at least one circular winging closest to the center of the concentric circle is wound in a direction opposite to that of the other windings; a sealed chamber in which a predetermined process is performed on a sample placed on a chuck therein through a reaction between plasma ions and reactive radicals; and a radio frequency (RF) power supply for providing RF electric power of a predetermined frequency to the ICP antenna coil in the source region.

In accordance with another aspect of the present invention, there is provided an antenna coil structure for generating inductive electric fields for used in an inductively-coupled plasma (ICP) generation apparatus. The antenna coil structure comprises at least one concentric circle-type central winding wound in a predetermined direction; and at least one concentric circle-type outer winding connected in series to the at least one central winding, the concentric circle-type outer winding being wound in a direction opposite to that of the at least one central winding.

### BRIEF DESCRIPTION OF THE DRAWINGS

The above and other objects, features and advantages of the present invention will become more apparent from the following detailed description when taken in conjunction with the accompanying drawings in which:

FIG. 1 is a perspective view of a general inductively-coupled plasma (ICP) generation apparatus;

FIG. 2 is diagram illustrating the distribution of inductive electric fields generated by an antenna coil in the general ICP generation apparatus;

FIG. 3 is a graph illustrating the density of plasma ions generated in a chamber of the general ICP generation apparatus;

FIG. 4 is a perspective view of an ICP generation apparatus according to an embodiment of the present invention;

FIGS. 5A to 5C are diagrams illustrating structures of antenna coils for an ICP generation apparatus according to embodiments of the present invention; and

FIGS. 6A to 6C are graphs illustrating a comparison between a distribution characteristic of magnetic fields generated from the antenna coil of the ICP generation apparatus according to an embodiment of the present invention and a distribution characteristic of magnetic fields generated from the conventional antenna coil.

### DETAILED DESCRIPTION OF THE PREFERRED EMBODIMENT

Several preferred embodiments of the present invention will now be described in detail with reference to the annexed drawings. In the following description, a detailed description of known functions and configurations incorporated herein has been omitted for conciseness.

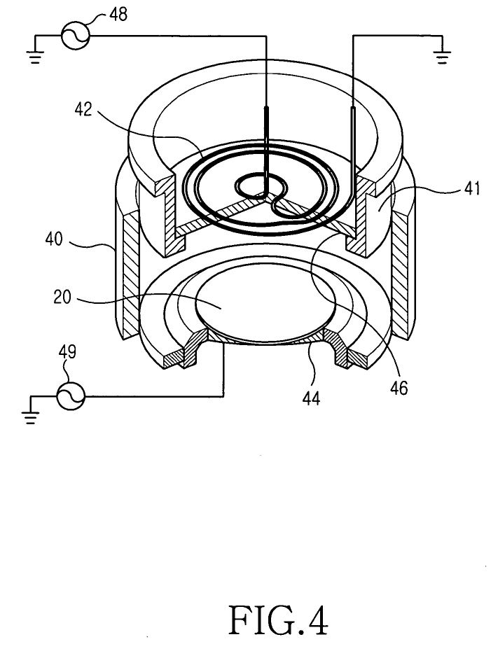

FIG. 4 is a perspective view of an inductively-coupled plasma (ICP) generation apparatus according to an embodiment of the present invention. Referring to FIG. 4, an ICP generation apparatus according to an embodiment of the present invention comprises of a source region 41 and a chamber 40, similar to that of the conventional ICP generation apparatus, and the source region 41 is separated from the chamber 40 by an insulating plate 46.

The chamber 40 includes therein a gas inlet (not shown) and a gas outlet (not shown), and further includes therein a chuck 44 on which a sample 20, such as a wafer or a glass substrate, is placed for processing. Within the source region 41 is mounted an ICP antenna coil 42 for generating inductive electric fields to generate plasma according to an embodiment of the present invention. The antenna coil 42 is connected to a radio frequency (RF) power supply 48 having a frequency range of between 1 to 30 MHz (commonly, 13.56 MHz).

In such an ICP generation apparatus, the inside of the chamber 40 is initially vacuumized and then reactive gas for generating plasma is injected into the chamber 40 at an appropriate pressure. Thereafter, the antenna coil 42 forms inductive electric fields within the chamber 40 according to the level and frequency of the RF electric power provided from the RF power supply 48. Plasma is generated by the inductive electric fields. In addition, electric power is applied to the chuck 44 from a second RF power supply 49 in order to control the energy of the ions incident on the sample 20. Between the RF power supply 48 and the antenna coil 42 (also between the RF power supply 49 and the chuck 44) is commonly provided an impedance matching circuit (not shown) for impedance matching.

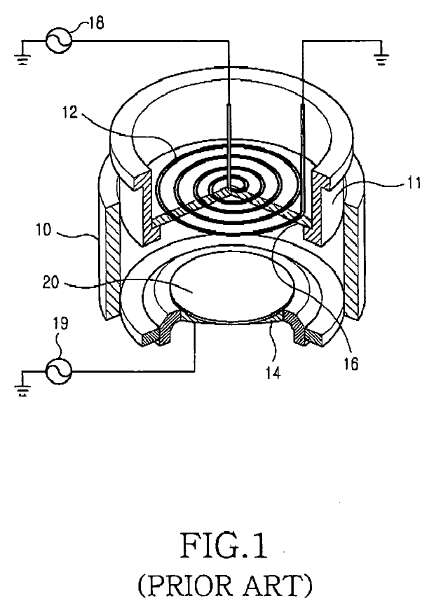

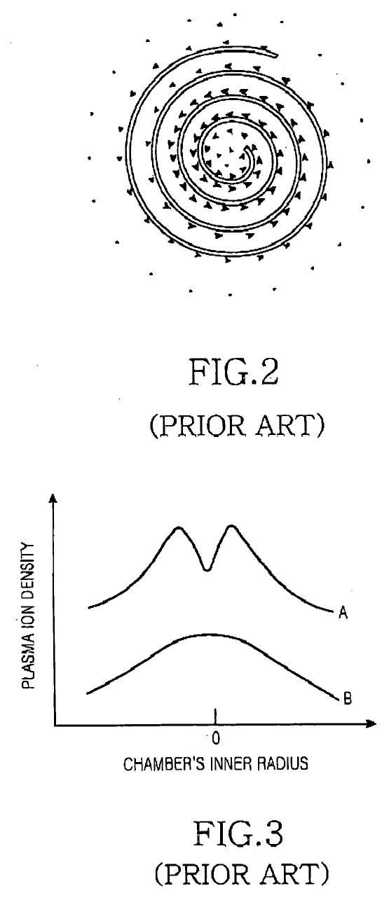

In this ICP generation apparatus, the antenna coil 42 has a serially-connected, single-lined concentric circle-type structure so that it is simple in structure and easy to manufacture and install. The antenna coil 42 has a different winding pattern than the winding patter of the conventional antenna coil 12 shown and described in FIGS. 1 to 3.

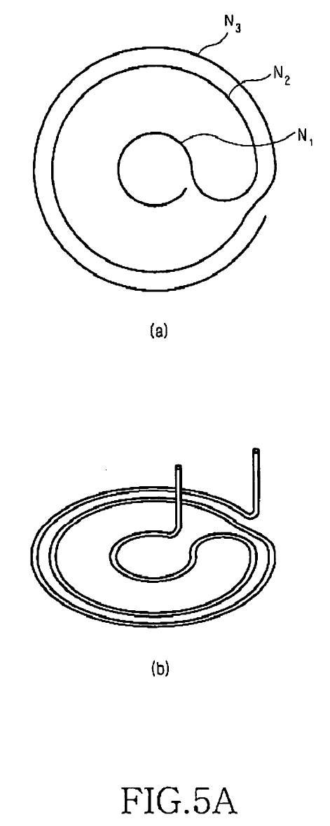

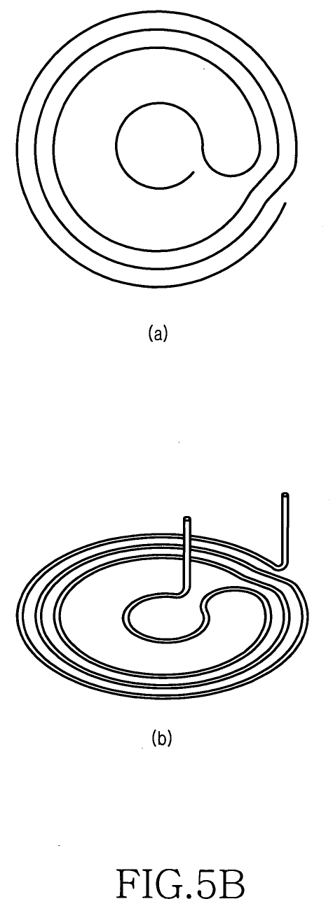

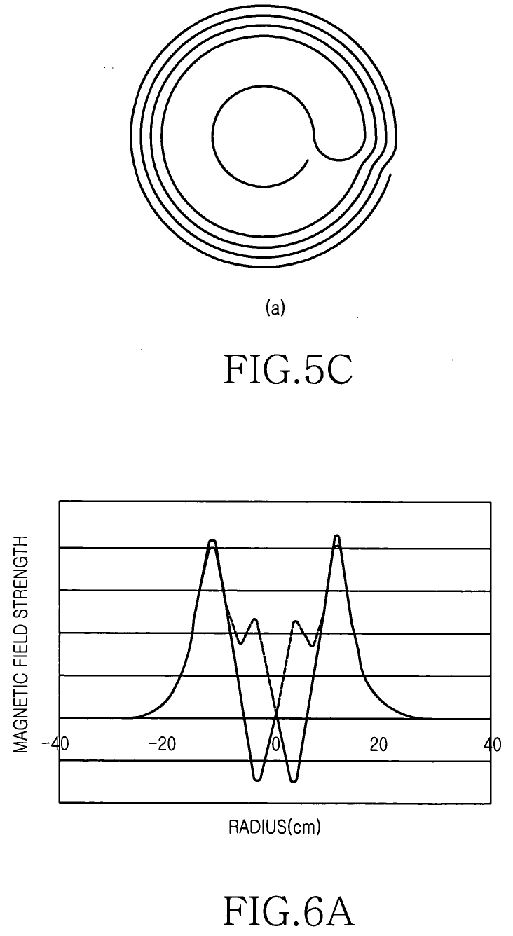

FIGS. 5A to 5C are diagrams illustrating various structures of the antenna coils for an ICP generation apparatus according to several embodiments of the present invention. In FIGS. 5A to 5C, the total number of windings of the antenna coil 42 is 3, 4 and 5, respectively. Referring to FIGS. 5A to 5C, the antenna coil 42 according to an embodiment of the present invention has a serially-connected concentric circle-type structure, and the total number of windings N of the antenna coil 42 is greater than 2. The winding closest to the center of a concentric circle is wound in a direction opposite than that of the other windings. The total number of central, opposite wound windings is represented by “n”. FIG. 5A shows that a first winding N., is wound in a different direction as to that of windings N₂ and N₃. N₂ and N₃ are wound in the same direction.

As described above, the structure of the antenna coil 42 according to an embodiment of the present invention is based on the simple structure of the conventional serially-wound helical antenna coil, and is characterized in that in order to secure plasma uniformity, the winding closest to the center of the concentric circle is wound in an opposite direction to the other windings. This is to improve the entire plasma uniformity by decreasing the strength of inductive electric fields at the central portion in the chamber 40 by virtue of cancellation effects of magnetic fields at the central portion by the central windings wound in the opposite direction to thus reduce plasma density at the central portion. The antenna coil 42 according to an embodiment of the present invention is characterized in that plasma uniformity can be controlled through a change in magnetic field distribution by the central windings wound in the opposite direction, and high plasma generation efficiency can also be secured because the total number of windings is greater than 2.

In order to describe effects of the antenna coil of the ICP generation apparatus on the plasma discharge efficiency and plasma uniformity, it will be assumed herein that the plasma reacts as an isotrope conductor having a particular electric conductivity σ. In an ICP source wherein a radius of a source having a symmetrical structure with respect to its central axis is much greater than the penetration depth of plasma, the strength of electric fields induced in a circumferential direction \hat{θ} can be expressed by Maxwell's equation of ∇×\vec{B}=jω_{rf}μₒε\vec{E} and simplified as shown in Equation (1) below.

$${E}_{θ} ≅ \frac{{B}_{r} ( r ) exp ( - z / δ )}{{jω}_{rf} {ɛμ}_{δ}} \qquad ( 1 )$$

In Equation (1), it is assumed that electromagnetic waves incident on the plasma, which reacts as an isotrope conductor is exponentially decreased according to the penetration depth 6. The inductive electric fields generated in this way generate a current on the surface of the plasma, and through this process, the plasma absorbs RF electric power.

Therefore, in an ICP discharging process, most of the electron heating phenomenon takes place in a region having a penetration depth 6 of about 1 to 2 cm from the surface of the plasma. The heated electrons generate plasma through collision with neutral particles. The generated plasma is diffused throughout the chamber through a diffusion process. The strength and distribution of magnetic fields formed by the antenna coil become very important factors used for determining plasma density and uniformity.

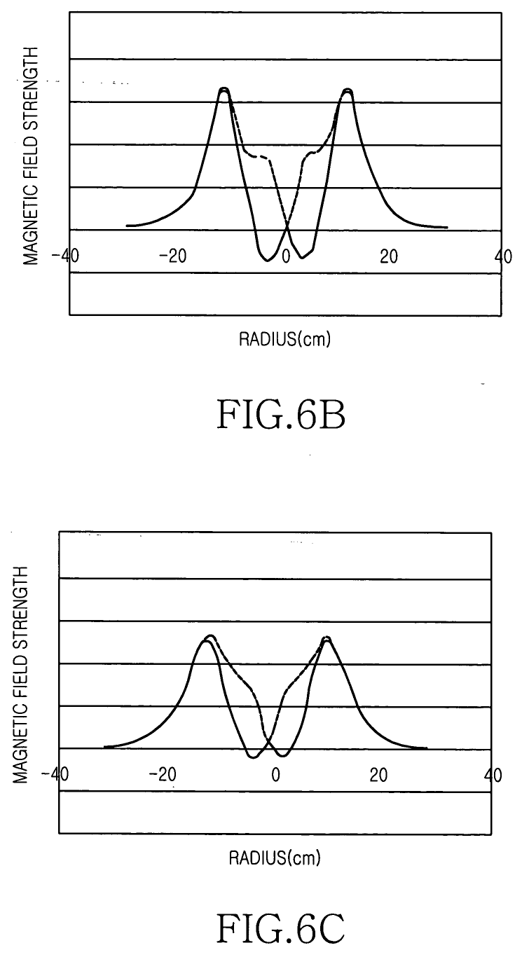

The plasma distribution characteristics of the multi-winding circular ICP antenna coil having the central winding wound in an opposite direction as that of the other windings according to an embodiment of the present invention will be described with reference to FIGS. 6A to 6C. FIGS. 6A to 6C are graphs illustrating a comparison between a distribution characteristic of magnetic fields generated from the antenna coil with n=1 of the ICP generation apparatus according to an embodiment of the present invention and a distribution characteristic of magnetic fields generated from the conventional antenna coil.

The antenna coil according to an embodiment of the present invention, shown by the solid line in the magnetic field distribution characteristics illustrated in the graphs of FIGS. 6A to 6C, has a structure of FIG. 5A in which the antenna coil has N=3 total windings, and n=1 central winding N, that has a different winding direction (or a current direction) from the other windings N₂ and N₃ for convenience, the current directions of the windings are represented by ‘−, +, +’. The antenna coil shown by a dotted-line in FIGS. 6A to 6C, has a structure where all the windings are wound in the same direction, the winding directions are represented by ‘+, +, +’. In both the new 3-winding antenna coil according to the present invention and the conventional 3-winding antenna coil, the radiuses of the 3 windings are 4, 12 and 13 cm, and each winding has a 1 cm² cross-sectional area.

In addition, the graphs of FIGS. 6A to 6C illustrate distribution characteristics of magnetic fields at places spaced apart by 2, 3 and 4 cm from the bottom surface of the windings, considering penetration depth and the insulating plate for keeping a vacuum state of the chamber.

As illustrated in FIGS. 6A to 6C, unlike in the conventional antenna coil represented by [+, +, +], in the new antenna coil represented by [−, +, +], having a one central winding wound in the opposition direction, the magnetic field components generated by a current flowing in the opposite direction are canceled at a place near its central axis, reducing strength of the magnetic fields. Therefore, plasma generation intensity is decreased at a place around the central axis, improving plasma uniformity.

FIGS. 6A to 6C illustrate the plasma generation efficiency and distribution characteristics based on a variation in the magnetic field components in a radial direction, obtained in a vacuum state. In practice though, even when plasma exists, the same discussion applies where the magnetic field components in the radial direction are exponentially reduced along a central axis (E_{∴}∝Bᵣ(r) ). Table 1 below shows plasma density and uniformity obtained as a modeling result on the plasma generated by the new antenna coil and the conventional antenna coil.

TABLE 1

| | | Plasma |
|---|---|---|
| Antenna Coil (4, 11, 13 cm) | Average plasma density | uniformity |
| Same current direction (+, +, +) | 3.29E+11 (/cm³) | 7.32% |
| Opposite current direction (−, +, +) | 3.20E+11 (/cm³) | 6.19% |

However, a portion of provided RF electric power does not contribute to the plasma generation due to the cancellation effects of magnetic fields by one central winding wound in the opposite direction in the antenna coil according to an embodiment of the present invention, causing unnecessary dissipation of the RF electric power. Therefore, when designing the antenna coil according to an embodiment of the present invention, an appropriate trade-off between efficient utilization of RF electric power and improvement in plasma uniformity must be considered, by minimizing the area occupied by one central winding with respect to the entire antenna coil, considering a geometrical structure of the chamber, and a frequency of the RF electric power in use.

While the invention has been shown and described with reference to a certain preferred embodiment thereof, it will be understood by those skilled in the art that various changes in form and details may be made therein without departing from the spirit and scope of the invention as defined by the appended claims.

1. An apparatus for generating inductively-coupled plasma (ICP), comprising:
a source region where an ICP antenna coil is mounted, the ICP antenna coil for generating inductive electric fields to generate plasma and having a serially-connected concentric circle-type structure, the total number of windings of the ICP antenna coil being greater than 2, the ICP antenna coil having a structure in which at least one circular winging closest to the center of the concentric circle is wound in a direction opposite to that of the other windings;
a sealed chamber in which is performed a reactionary process between plasma ions and reactive radicals; and
a radio frequency (RF) power supply for providing RF electric power of a predetermined frequency to the ICP antenna coil in the source region.

2. The apparatus of claim 1, further comprising a separate RF power supply for providing RF electric power a chuck located within the sealed champer in order to control the energy of the ions incident on a sample placed on the chuck.

3. An antenna coil structure for generating inductive electric fields for used in an inductively-coupled plasma (ICP) generation apparatus, comprising:
at least one concentric circle-type central winding wound in a predetermined direction; and
at least one concentric circle-type outer winding connected in series to the central winding, the concentric circle-type outer winding wound in a direction opposite to that of the at least one central winding.
